(19) United States
(12) Patent Application Publication
(10) Pub. No.: US 2026/0361314 A1
(43) Pub. Date: Nov. 12, 2026

(54) METHODS AND APPARATUS TO REDUCE METASTABILITY ERRORS IN AN ANALOG-TO-DIGITAL CONVERTER

(71) Applicant: Texas Instruments Incorporated, Dallas, TX (US)

(72) Inventors: Sai Vikas Kandimalla, Miryalaguda (IN); Visvesvaraya Appala Pentakota, Bangalore (IN); Neeraj Shrivastava, Bangalore (IN)

(21) Appl. No.: 19/402,496

(22) Filed: Nov. 26, 2025

(30) Foreign Application Priority Data
Mar. 13, 2025 (IN) 202541022655

(51) Int. Cl. H03M 1/12; H03K 19/20; H03M 1/34; H03M 1/50

(52) U.S. Cl. CPC H03M 1/1205; H03K 19/20; H03M 1/34; H03M 1/50

(57) ABSTRACT

An example apparatus includes: a first set of comparators configured to compare a sampled analog voltage to first thresholds, the first thresholds being at first indices of a set of thresholds; a second set of comparators configured to compare the sampled analog voltage to second thresholds, the second thresholds being at second indices of the set of thresholds, the second indices different than the first indices; a metastability detection circuit configured to determine whether one of the first set of comparators or the second set of comparators is metastable; and a multiplexer circuit configured to output a digital signal corresponding to the first residual voltage based on a comparator of the second set of comparators being metastable.

### CROSS-REFERENCE TO RELATED APPLICATION

This application claims the benefit of and priority to Indian Provisional Patent Application No. 202541022655, filed Mar. 13, 2025, which is hereby incorporated herein by reference in its entirety.

### TECHNICAL FIELD

This disclosure relates generally to an electronic system and method, and, in particular embodiments, to a method and apparatus to identify a state change of a switch.

### BACKGROUND

A pipelined analog-to-digital converter (ADC) converts an analog input signal to a digital output signal. Pipelined ADCs have multiple cascaded stages, where each stage resolves a few bits. Each stage of the pipelined ADC may include a sampler, a sub-ADC (e.g., a flash ADC), a digital-to-analog converter (DAC), a subtractor, and a gain amplifier. An analog input signal is sampled, and the flash ADC in the first stage quantizes the sample to a certain number of bits. The bits are fed to a similar sized DAC, and the analog output of the DAC is subtracted from the input by the subtractor. The residue (e.g., the remaining part of an analog signal that has not yet been fully digitized by a stage) is then amplified with a gain amplifier and fed to the next stage. The next stage does the same thing for a certain number of bits, and so on until the entire digital sample is created. The last ADC resolves the final bits. The resolved bits may be time-aligned with shift registers before going to the next stage (such as error correction). This allows the stages to work in parallel on different samples.

### SUMMARY

In accordance to an embodiment, an apparatus including: a first set of comparators configured to compare a sampled analog voltage to first thresholds, the first thresholds being at first indices of a set of thresholds; a second set of comparators configured to compare the sampled analog voltage to second thresholds, the second thresholds being at second indices of the set of thresholds, the second indices different than the first indices; a first set of capacitors configured to decrease the sampled analog voltage by a first reference voltage based on the outputs of the first set of comparators, the decreased sampled analog voltage corresponding to a first residual voltage; a second set of capacitors configured to decrease the sampled analog voltage by a second reference voltage based on the outputs of the second set of comparators, the decreased sampled analog voltage corresponding to a second residual voltage; a metastability detection circuit configured to determine whether one of the first set of comparators or the second set of comparators is metastable; and a multiplexer circuit configured to output a digital signal corresponding to the first residual voltage based on a comparator of the second set of comparators being metastable.

In accordance to an embodiment, an apparatus including: a sample and hold circuit having an input and an output; a flash circuit including an input, first outputs and second outputs, the input of the flash circuit coupled to the output of the sample and hold circuit, the flash circuit including: a set of reference terminals, each reference terminal of the set of reference terminals corresponding to a different reference voltage, the set of reference terminals including a first subset of the set of reference terminals and a second subset of the set of reference terminals, the first subset of the set of reference terminals corresponding to a first parity of a sequence and the second subset of the set of reference terminals corresponding to a second parity of the sequence; a first set of comparators, each having a first input, a second input, and an output, the first inputs of the first set of comparators coupled to the output of the sample and hold circuit, the second inputs of the first set of comparators coupled to corresponding ones of the first subset of the set of reference terminals, the outputs of the first set of comparators coupled to corresponding ones of the first outputs of the flash circuit; and a second set of comparators, each having a first input, a second input, and an output, the first inputs of the second set of comparators coupled to the output of the sample and hold circuit, the second inputs of the second set of comparators coupled to corresponding ones of the second subset of the set of reference terminals, the outputs of the second set of comparators coupled to corresponding ones of the second outputs of the flash circuit; a buffer having an input and an output, the input of the buffer coupled to the output of the sample and hold circuit; a first set of capacitors, each having a first terminal and a second terminal, the first terminals of the first set of capacitors coupled to the output of the buffer, the second terminals of the first set of capacitors coupled to a first reference voltage supply through corresponding first switches and a ground terminal through corresponding second switches, control terminals of the of the first switches and second switches coupled to corresponding outputs of the first set of comparators; a second set of capacitors, each having a first terminal and a second terminal, the first terminals of the second set of capacitors coupled to the output of the buffer, the second terminals of the second set of capacitors coupled to a second reference voltage supply through corresponding third switches and the ground terminal through corresponding fourth switches, control terminals of the of the third and fourth switches coupled to corresponding outputs of the second set of comparators; a first amplifier having an input and an output, the input of the first amplifier coupled to the first terminals of the first set of capacitors, the output of the first amplifier coupled to a subsequent stage; and a second amplifier having an input and an output, the input of the second amplifier coupled to the first terminals of the second set of capacitors, the output of the second amplifier coupled to the subsequent stage.

In accordance to an embodiment, a method including: sampling an input analog voltage; generating a first residual voltage based on the sampled input analog voltage and a first set of comparisons of the sampled input analog voltage to a first set of thresholds; generating a second residual voltage based on the sampled input analog voltage and a second set of comparisons of the sampled input analog voltage to a second set of thresholds; generating a first digital output corresponding to the input analog voltage based on the first set of comparisons and a third set of comparisons based on the first residual voltage; generating a second digital output corresponding to the input analog voltage based on the second set of comparisons and a fourth set of comparisons based on the second residual voltage; and generating a final digital output by averaging the first digital output and the second digital output.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is a block diagram of an example pipelined ADC, according to an embodiment of the present disclosure;

FIG. 2A is a circuit implementation of one of the stages of the pipelined ADC of FIG. 1, according to an embodiment of the present disclosure;

FIG. 2B is a circuit implementation of the flash circuit of FIG. 2A, according to an embodiment of the present disclosure;

FIG. 3A is an example output stage of the pipeline ADC of FIG. 1, according to an embodiment of the present disclosure;

FIG. 3B is an example table representative of the output of the output stage of FIG. 3A, according to an embodiment of the present disclosure;

FIG. 4 is an example circuit implementation of the metastability detection comparison circuit of FIG. 2A for a comparator in the flash circuit of FIG. 2B, according to an embodiment of the present disclosure;

FIG. 5 is a circuit implementation of one of the stages of the pipelined ADC of FIG. 1 with backend time-to-digital converters, according to an embodiment of the present disclosure;

FIG. 6 is a flowchart representative of example machine-readable instructions or example operations that may be at least one of executed, instantiated, or performed using an example programmable circuit implementation of the aligned and error correction circuit and/or the output stage of FIGS. 1 and 3A, according to an embodiment of the present disclosure; and

FIGS. 7A, 7B, 7C includes timing diagrams to illustrate metastability events for an ODD ADC, and EVEN ADC, and the ADC described herein, according to an embodiment of the present disclosure.

Corresponding numerals and symbols in different figures generally refer to corresponding parts unless otherwise indicated. The figures are drawn to clearly illustrate relevant aspects of preferred embodiments and are not necessarily drawn to scale.

### DETAILED DESCRIPTION

The making and using of the embodiments disclosed are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The description below illustrates various specific details to provide an in-depth understanding of several example embodiments according to the description. The embodiments may be received without one or more of the specific details, or with other methods, components, materials, and the like. In some cases, known structures, materials, or operations are not shown or described in detail so as not to obscure the different aspects of the embodiments. References to “an embodiment” or “an example” in this description indicate that a particular configuration, structure, or feature described in relation to the embodiment is included in at least one embodiment. Consequently, phrases such as “in one embodiment” or “in one example” that may appear at different points of the present description do not necessarily refer exactly to the same embodiment. Furthermore, specific formations, structures or features may be combined in any appropriate manner in one or more embodiments.

Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events.

Embodiments of the present disclosure are described in specific contexts, e.g., a pipelined ADC in a wireless circuit (e.g., a transmitter, a receiver, a transceiver). Some embodiments may be used in other systems, such as in telecommunication systems, digital imaging systems, medical imaging systems, consumer electrics, industrial automation systems, radar systems, and/or any other system that may utilize an ADC.

In an embodiment, a circuit is disclosed to reduce and/or eliminate metastability errors in an ADC by dividing a stage of an ADC into two halves (e.g., an even half and an odd half), each half having separate sampling capacitors and residue amplifiers. Metastability may occur when a comparator fails to produce a definite logical output within an allotted time (e.g., raining in an indeterminate, unstable state). Each half of the stage can generate digital outputs and, if one half corresponds to metastability, the outputs of the metastable half are discarded. For example, instead of using 16 comparators to compare an input sample voltage to 16 different thresholds, examples disclosed herein use 8 comparators to compare the input same to 8 odd increments of the 16 thresholds and 8 even increments of the 16 thresholds. The outputs of the even comparators are used to generate a first residual voltage for a first TDC, and the outputs of the odd comparators are used to generate a second residual voltage for a second TDC. Also, the outputs of the even and odd comparators and the TDCs are transmitted to an output stage to generate an output digital value. Some embodiments identify whether any one of the odd comparators or the even comparators is metastable, because only one comparator of either the odd comparators or the even comparators can be metastable for a particular input voltage. If the odd comparators include a metastable comparator, some embodiments use the results of the even comparators and the TDCs to generate a digital output. If the even comparators include a metastable comparator, some embodiments use the results of the odd comparators to generate a digital output. If none of the comparators is metastable, some embodiments use an average of the odd and even comparators to generate a digital output. Thus, examples disclosed herein eliminate metastability errors in ADC structures.

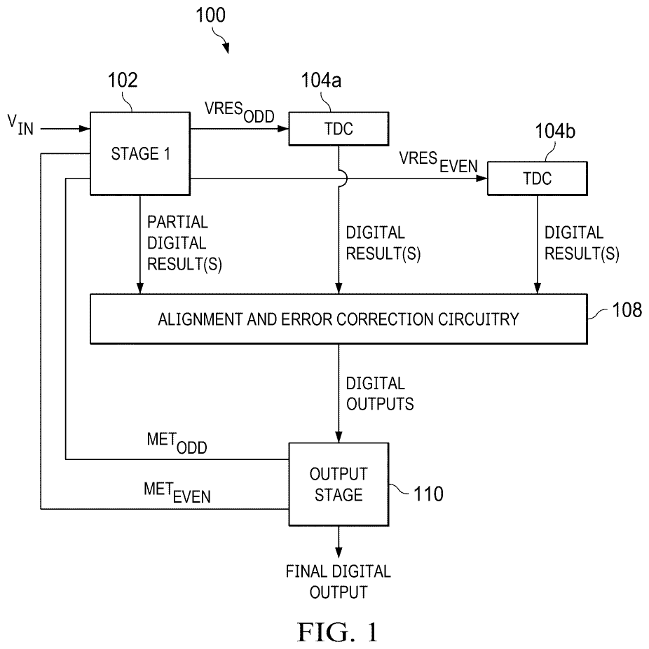

FIG. 1 is a block diagram of an example pipeline ADC 100, according to an embodiment of the present disclosure. The pipeline ADC 100 includes first stage 102, a second stage implemented by TDCs 104a, 104b, and alignment and error correction circuit 108, and an output stage 110. Although the pipeline ADC 100 includes 2 stages (e.g., stage 102 and TDC 104a, 104b), there may be any number of stages. Other implementations are also possible.

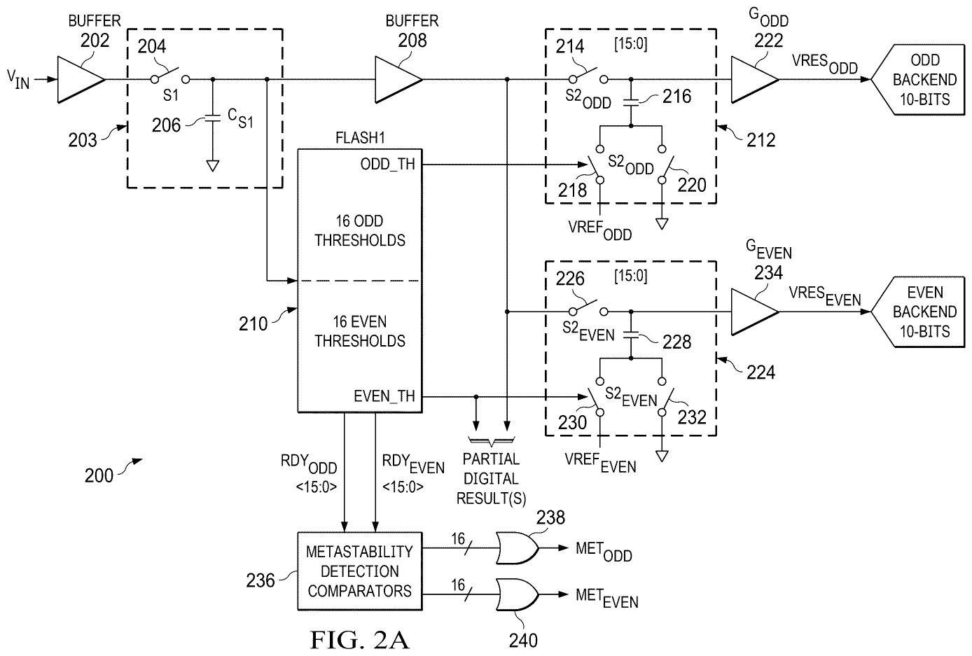

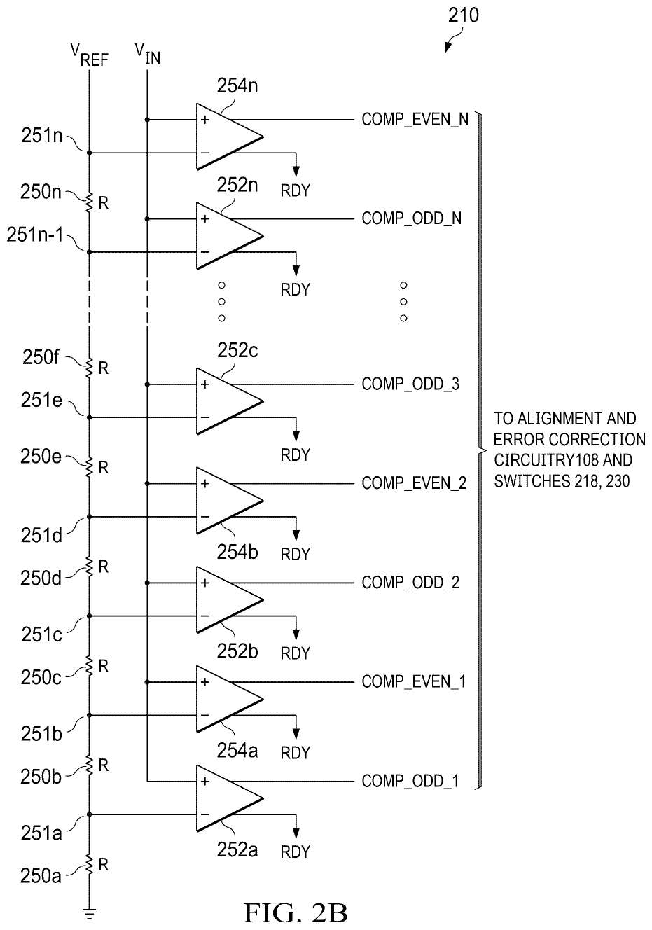

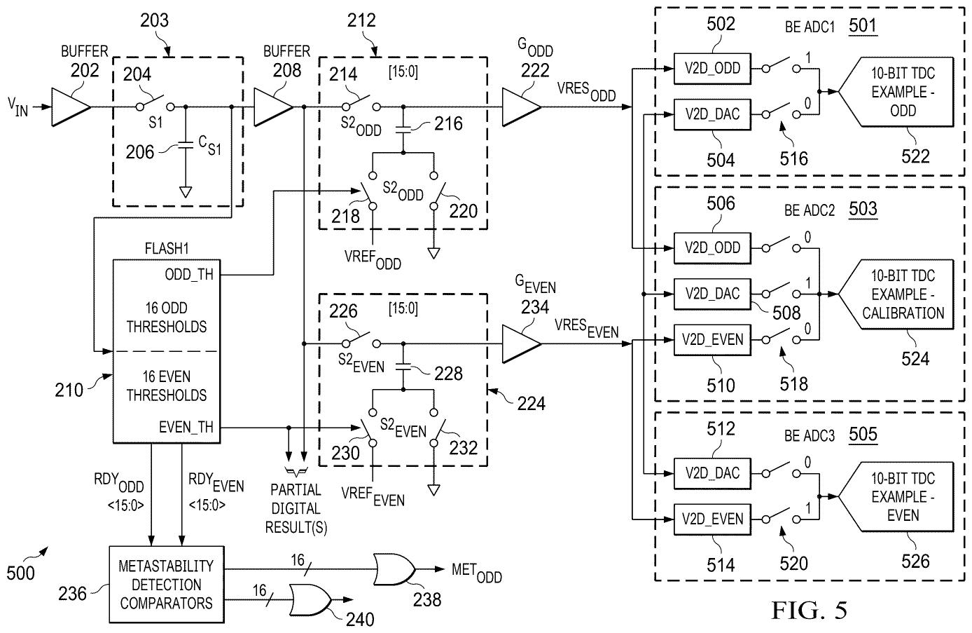

In normal operation, the first stage 102 receives an input analog signal. The first stage 102 generates sub-codes (e.g., an odd-based sub-code and an even-based sub-code) corresponding to a voltage level of the input analog signal. Additionally, the stage 102 generates amplified residual signals (e.g., VRES_{ODD} and VRES_{EVEN}) as an input to the TDCs 104a, 104b. For example, stage 102 converts the input analog voltage to sub-codes (also referred to as partial digital results) that are provided to the alignment and error correction circuit 108 and amplified residual signals that is output to the TDCs 104a, 104b. Thus, stage 102 partially resolves the input analog signal and generates an unresolved residue to be resolved by the TDCs 104a, 104b. The TDCs 104a, 104b resolve the corresponding amplified residue by converting the residue analog voltage into a digital output by converting the arrival time of a residue signal (based on a voltage to delay converter) to a digital code. In some examples, the TDC 104a, 104b are metastability free but has a lower resolution, which is sufficient for the lowest significant bits. In some examples, the TDCs 104a, 104b can be replaced with different type of stage (e.g., ADCs). Additionally, the ADC 100 may include a third TDC used during calibration of the TDCs 104a, 104b, as further described below in conjunction with FIG. 5. As further described below, the first stage 102 can generate first (e.g., based on even-incremented thresholds) partial digital results and residue and second (e.g., based on odd-incremented thresholds) partial digital results and residue. Additionally, the first stage 102 can determine if the first partial digital results/residue corresponds to metastability or if the second partial digital results/residues correspond to metastability. The first stage 102 outputs a signal indicative of metastability for an odd-incremented ODD threshold to the output stage 110 via the MET_{ODD} terminal and outputs a signal indicative of the metastability for an even-incremented EVEN threshold to the output stage via the MET_{EVEN} terminal. The first stage 102 is further described below in conjunction with FIG. 2A.

In an embodiment, the alignment and error correction circuit 108 obtains the partial digital result(s) from the stage 102 and the digital result(s) from the TDCs 104a, 104b and generates an overall code representing the strength of the sampled input analog voltage/signal. For example, the alignment and error correction circuit 108 may perform a weighted addition of the sub-codes to generate two digital outputs (e.g., one based on the even incremented threshold, and one based on the odd incremented threshold). Additionally, the alignment and error correction circuit 108 can estimate and/or mitigate gain and offset mismatch for the two digital outputs to minimize absolute sample error in the presence of metastability. For example, the non-metastable samples digital output can be used to estimate gain/offset errors. In case of non-metastability both ODD/EVEN ADCs should give same output code, any gain/offset will cause mismatch in these codes, which can be calculated using this data itself. The alignment and error correction circuit 108 outputs the two digital outputs (e.g., the even threshold-based digital output and the odd threshold-based digital output) after correcting for gain and offset mismatch to the output stage 110.

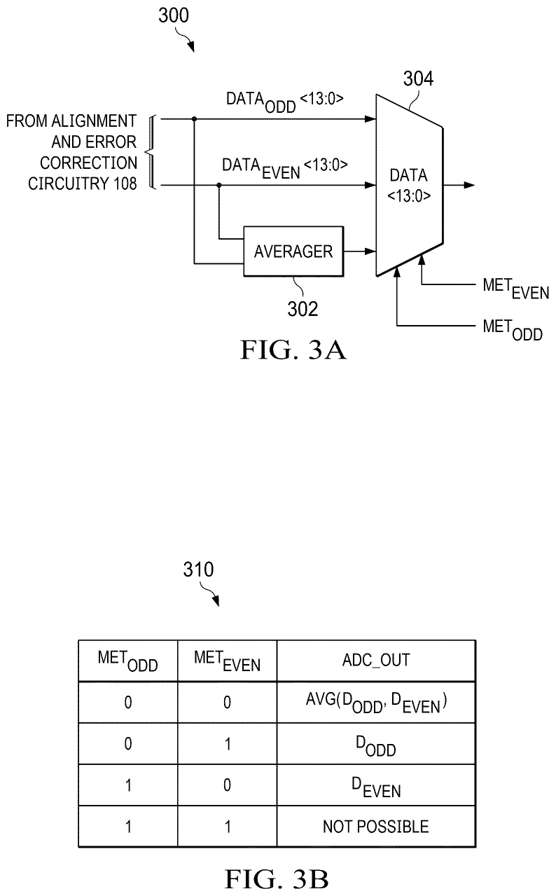

In an embodiment, the output stage 110 generates a final digital output value corresponding to the input analog voltage based on one or more of the first digital output and/or the second digital output of the alignment and error correction circuit 108 based on the metastability indication signals from the stage 102. For example, if the metastability signals indicate that one of the comparators in the stage 102 that corresponds to the odd-increment thresholds is metastable, the output stage 110 outputs the digital signal that corresponds to the even-increment thresholds. If the metastability signals indicate that one of the comparators in the stage 102 that correspond to the even-increment thresholds is metastable, the output stage 110 outputs the digital signal that corresponds to the off-increment thresholds. If the metastability signals indicate that none of the comparators in the stage 102 are metastable, the output stage 110 outputs the final digital output as an average of the two digital outputs of the alignment and error correction circuit 108. The output stage 110 is further described below in conjunction with FIG. 3.

In some embodiments, alignment and error correction circuit 108 may be implemented using (e.g., only) synthetized logic. In some embodiments, alignment and error correction circuit 108 may be implemented with a generic or custom processor or controller coupled to a memory and configured to execute instructions in such memory. In some embodiments, control circuit 130 may be implemented using a field programmable gate array (FPGA). In some embodiments, control circuit 130 includes combinational logic, sequential logic, programmable logic (e.g., in combination with program memory), or the like, or a combination thereof. In some embodiments, control circuit 130 includes a state machine. In some embodiments, control circuit 130 includes a hardware accelerator. Other implementations may also be possible.

FIG. 2A is a circuit implementation of an example ADC stage 200 of a pipelined ADC, according to an embodiment of the present disclosure. The ADC stage 200 may be used to implement the first stage 102 of the pipelined ADC 100 of FIG. 1. The ADC stage 200 includes example buffers 202, 208, an example sampling circuit 203, an example switch 204, an example sampling capacitor 206, example flash circuit 210 (also referred to as a flash ADC converter), example residue generation circuits 212, 224, example switches 214, 218, 220, 226, 230, 232, example capacitors 216, 228, example amplifiers 222, 234, example metastability detection circuit 236, and example logic gates 238, 240. Although FIG. 2A illustrates a particular ADC sample stage 200, the first stage 102 can be implemented in a different manner. Other implementations may also be possible.

In operation, the buffer 202 obtains an analog input signal and outputs the analog input signal to the sampling circuit 203. When the switch 204 is closed, the input analog signal is sampled onto the sampling capacitor 206 to generate a sampled voltage corresponding to the input analog signal. A controller or clock signal generator can output a clock/control signal to close and open the switch 204. The clock signal may be complementary to a second clock signal that is used to control the switches 214, 220, 226, 232. Thus, during a first duration of time, when the switch 204 is closed and the switches 214, 220, 226, 232 are open, the input voltage is sampled onto the capacitor 206. During a second duration of time, when the switch 204 is open and the switches 214, 220, 226, 232 are closed, the input signal is sampled onto the capacitors 216, 228 and the flash circuit 210 performs multiple comparisons to generate output signals to decrease the sampled input signal based on the outputs of the flash circuit 210 to generate residual voltages, as further described below.

In an embodiment, the flash circuit 210 includes a plurality of comparators that compare the sampled input voltage to various thresholds. The output of the comparisons is used to control the switches 218, 230 (e.g., by applying a voltage to the control terminals of the switches 218, 230) of the plurality of residue generation circuit 212, 224, as further described below. Additionally, the output of the plurality of comparators in the flash circuit 210 is output to the alignment and error correction circuit 108 of FIG. 1 to represent the partial digital results of the stage 200. Additionally, the flash circuit 210 generates a ready signal that triggers after each comparator generates a valid result. In some examples, the ready signal is output by each comparator when the comparator generates a valid result. In some examples, additional circuit(s) can generate the ready signal based on the output(s) of the comparator(s). For example, if the comparator is a differential comparator with two complementary outputs, the outputs of the comparator can be preset to output the same output (e.g., both logic ‘0’ or both logic ‘1’). When the output of the comparator is ready, one of the outputs will switch to a different logic based on the comparison. Accordingly, when the comparator is processing the inputs, the outputs of the comparator are the same and when the comparator output is valid, the comparator outputs are different. Thus, a circuit (e.g., an exclusive OR (XOR) logic gate), can determine when the output of the comparator changes from being the same to being different, which corresponds to the output of the comparator being ready/valid, and output the ready signal accordingly.

In an embodiment, the comparators of the flash circuit 210 are grouped into two groups or subsets. For example, comparators that compare the input sampled voltage to odd increments of thresholds (e.g., (2n+1)X Volts, where n is a counting number and X is predefined minimum threshold, such as 100 mV, 300 mV, 500 mV, etc.) and even increment thresholds (e.g., (2n)X Voltage, such as 200 mV, 400 mV, 600 mV, etc.). In an embodiment, the flash circuit 210 includes 32 comparators for 16 odd threshold comparisons (e.g., comparisons corresponding to odd increments a set of threshold voltages) and 16 even threshold comparisons (e.g., comparisons corresponding to even increments a set of threshold voltages), resulting in 16 ready ODD outputs, 16 ready EVEN outputs, 15 ODD threshold comparison outputs, and 16 EVEN threshold comparison outputs. However, the flash circuit 210 may include any number of comparisons. An example implementation of the flash circuit 210 is further described below in conjunction with FIG. 2B.

In some embodiments, the odd residue generation circuit 212 includes 16 residue generation circuits coupled in parallel for the 15 odd-increment thresholds comparisons of the flash circuit 210. For example, each of the residue generation circuit 212 is coupled to the output of the buffer to obtain the sampled input voltage from the sampling circuit 203. Each of the residue generation circuit 212 include the sampling capacitor 216 (e.g., each of the capacitors 216 having the same capacitance) and switches 214, 218, 220. The switches 218 of the 16 residue generation circuit 212 are controlled by a corresponding odd-increment comparators of the flash circuit 210. For example, a first comparator corresponding to a 100 mV comparison controls a first switch of a first one of the residue generation circuit 212, a second comparator corresponding to a 300 mV comparison controls a second switch of a second one of the residue generation circuit 212, etc. The residue generation circuit 212 can operate similar to a digital to analog converter, where the digital outputs of the flash circuit 210 are used to control the switches 218 of the various odd residue generation circuit 212 so that respective ones of the capacitors 216 of the different odd residue generation circuit 212 are coupled to the ground terminal and other respective ones of the capacitor 216 are coupled to a first reference voltage supply/reference voltage terminal (VRES_{ODD}), thereby generating an analog residue signal at the input of the amplifier 222. The amplifier 222 amplifies the analog residual value to generate an output odd residual voltage (VRES_{ODD}), which is output to a subsequent stage (the TDC 104a).

In some embodiments, the even residue generation circuit 224 includes 16 residue generation circuits coupled in parallel for the 15 even-increment thresholds comparisons of the flash circuit 210. For example, each of the residue generation circuit 224is coupled to the output of the buffer to obtain the sampled input voltage from the sampling circuit 203. Each of the residue generation circuit 224 include the sampling capacitor 228 (e.g., each of the capacitors 228 having the same capacitance) and switches 226, 230, 232. The switches 230 of the 16 residue generation circuit 224 are controlled by a corresponding even-increment comparators of the flash circuit 210. For example, a first comparator corresponding to a 200 mV comparison controls a first switch of a first one of the residue generation circuit 224, a second comparator corresponding to a 400 mV comparison controls a second switch of a second one of the residue generation circuit 224, etc. The residue generation circuit 224 can operate similar to a digital to analog converter, where the digital outputs of the flash circuit 210 are used to control the switches 230 of the various even residue generation circuit 224 so that respective ones of the capacitors 228 of the different even residue generation circuit 224 are coupled to ground and other respective ones of the capacitor 228 are coupled to a second reference voltage supply/reference voltage terminal/reference voltage source (VRES_{EVEN}), thereby generating an analog residue signal at the input of the amplifier 234. The amplifier 234 amplifies the analog residual value to generate an output even residual voltage (VRES_{EVEN}), which is output to the TDC 104b. In some examples, the first reference voltage supply/terminal/source (VRES_{ODD}) is different than the second reference voltage supply/reference voltage terminal (VRES_{EVEN}), even though they correspond to the same reference voltage amount. If both the odd switches 218 were coupled to the same voltage supply source as the even switches 220, metastability on the odd side can cause disturbance on the even side through the shared voltage supply source/terminal. Thus, separate voltage supply source/terminals are used for the even residual generation circuit 224 and the odd residual generation circuit 212 to avoid such disturbance.

In an embodiment, the metastability detection circuit 236 determines whether the comparators in the flash circuit 210 are metastable based on a predetermined duration of time for the comparators to output a ready signal. As described above, a comparator is metastable when the comparator fails to produce a definite logical output within an allotted time (e.g., raining in an indeterminate, unstable state). For comparators, the closer that the input voltage is to the threshold, the longer the amount of time that the comparator needs to generate a valid result. Accordingly, an input voltage that is close to a threshold may result in a metastable comparator. The metastability detection circuit 236 compares the ready signals from the flash circuit 210 to a reference clock to determine if any one of the comparators is metastable (e.g., because the ready signal did not occur within a threshold amount of time based on the reference clock). Because the comparators of the flash circuit 210 correspond to different thresholds, only one comparator, if any, will be metastable (e.g., if the input voltage is near one threshold, then it is not near the other thresholds). Accordingly, if one of the comparators for an odd increment threshold is metastable, then none of the comparators for the even increment threshold are metastable and vice versa. The metastability detection circuit 236 outputs a signal for each comparator of the flash circuit 210 to indicate whether each corresponding comparator is metastable or not.

In an embodiment, the metastability detection circuit 236 outputs the metastability indication signals for the odd-increment threshold comparators to the logic OR gate 238. Additionally, the metastability detection circuit 236 outputs the metastability indication signals for the even-increment threshold comparators to the logic OR gate 240. As described above, in some examples, at most one comparator can be metastable at a time. Thus, the logic OR gate 238 performs a logic OR function for all the odd metastability indication signals to generate the MET_{ODD} signal that identifies if any of the odd-increment threshold comparators are metastable. Additionally, the logic OR gate 240 performs a logic OR function for all the even metastability indication signals to generate the MET_{EVEN} signal that identifies if any of the even-increment threshold comparators are metastable. As further described below, an output stage uses the MET_{ODD} and MET_{EVEN} signal to generate a final digital output signal for the ADC.

FIG. 2B is a circuit implementation of the example flash circuit 210 of FIG. 2A, according to an embodiment of the present disclosure. The flash circuit 210 includes example resistors 250a-n, example reference terminals 251a-n, example odd-increment comparators 252a-n, and example even-increment threshold comparators 254a-n. Although the flash circuit 210 includes N (e.g., 32) comparators and N (e.g., 32) resistors, the flash circuit 210 may include any number of resistors and any number or type of comparators. Other implementations are also possible.

In an embodiment, the resistors 250a-n are coupled in series between a reference voltage terminal (Vref) and a common terminal (ground). The resistors 250a-n each correspond to the same resistance so that the voltage at each terminal 251a-251 is uniformly incremented up to Vref (e.g., where the differences between subsequent thresholds are the same between Vref and ground). For example, if there are 10 resistors 250a-n and Vref is 1 V, then the reference voltage at the first node 251a is 100 mV, the reference voltage at the second node 251b is 200 mV, the reference voltage at the third node 251c is 300 mV, . . . , and the voltage at the last reference terminal 251n is 1 V. In some examples, the nodes 251a-n can be grouped into a first subset of even-based reference terminals (e.g., 251b, 251d, . . . , 251n corresponding to a sequence of even thresholds) and odd-based reference terminals (251a, 251c, . . . , 215n-l, corresponding to a sequence of odd thresholds). However, in some examples, the resistances of one or more of the resistors 250a-n may be different to generate non-uniform increments of the reference voltages between ground and the Vref terminal. Each reference terminal 251a-n is coupled to the inverting input of a corresponding comparator 252a-n, 254a-n and the sampled input voltage is coupled to the non-inverting input terminal of all the comparators 252a-n, 254a-n. Accordingly, each comparator 252a-n, 254a-n compares the sampled input voltage with a different threshold, where the comparators 252a-n compare the sampled input voltage to a first parity (e.g., odd) increment thresholds and the comparators 252a-n compare the sampled input voltage to a second parity (e.g., even) increment thresholds. At the start of a comparison, the comparators 252a-n, 254a-n set the ready output to a first logic signal (e.g., ‘0’) and after the respective comparators 252a-n, 254a-n adjust the ready output to a second logic signal (e.g., ‘1’) to indicate that the output of the corresponding comparator is ready/valid. However, as described above, there may be additional circuit(s) to determine when the output of a comparator is ready/valid (e.g., a XOR gate coupled to both outputs of a differential comparator).

In an example, if the Vref is 1 V, there are 10 comparators (e.g., 5 comparators 252 a-n corresponding to odd increment thresholds 252a-n and 5 comparators 254a-n corresponding to even increment thresholds), then the thresholds of the 10 comparators correspond to 100 mV threshold increments. If the input voltage is 890 mV, the first 8 comparators output a logic high voltage. For example, because the input reference voltage of the first comparator 252a is 100 mV and 790 mV is higher than 100 mV, the first comparator 252a outputs a logic high voltage. The last 2 comparators 252n, 254n output a logic low voltage. For example, because the last 2 comparators 252n, 254n have input reference voltages of 900 mV and 1V, respectively, the voltage at the inverting terminal of the corresponding 2 comparators will be higher than the 890 mV input voltage. Because 890 mV is closest to the 900 mV reference voltage of the odd-increment threshold comparator 252n, the comparator 252 may be metastable because it may take longer for the comparator 252n to output a valid/ready comparison output. Because the input voltage is further away from the reference voltages of the remaining comparators, the remaining comparators will not be metastable. Accordingly, the metastability detection circuit 236 of FIG. 2A accesses the ready signals of the comparators 252a-n, 254a-n to determine whether any of the comparators 252a-n, 254a-n are metastable, as further described above. Additionally, the outputs of the odd-based comparators 252a-n (e.g., Comp_Odd_1, Comp_Odd_2, . . . Comp_Odd_N) are used to control the corresponding switches 218 of the odd residual generation circuit 212 (e.g., Comp_Odd_1 controls a first switch 218 of the first odd residual generation circuit 212, Comp_Odd_2 controls a second switch 218 of a second odd residual generation circuit 212, etc.). Additionally, the outputs of the even-based comparators 252a-n (e.g., Comp_Even_1, Comp_Even_2,. Comp_Even_N) are used to control the corresponding switches 230 of the even residual generation circuit 224 of FIG. 2A.

FIG. 3A is a circuit diagram of an example output stage 300, according to an embodiment of the present disclosure. The example output stage 300 includes example averager circuit 302 and example multiplexer circuit 304. Other implementations are also possible.

The averager circuit 302 determines the average of the odd-based digital signal (DATA_{ODD}) output by the alignment and error correction circuit 108 and the even based digital signal (DATA_{EVEN}) output by the alignment and error correction circuit 108. The averager circuit 302 outputs the average of the digital signal to a third input of the multiplexer circuit 304.

The multiplexer circuit 304 may include one or more multiplexers and/or logic gates to generate a final digital output for the ADC 100 of FIG. 1 that corresponds to the input analog voltage. The multiplexer circuit 304 includes a first input to receive the odd-based digital signal (DATA_{ODD}), a second input to receive the even-based digital signal (DATA_{EVEN}), and a third input to receive the average of the odd-based digital signal (DATA_{ODD}) and the even-based digital signal (DATA_{EVEN}). The multiplexer circuit 304 also includes two select terminals (also referred to as select input terminals). The first select terminal of the multiplexer circuit 304 receives the MET_{ODD} signal from the logic OR gate 238 of FIG. 2A and the second select terminal of the multiplexer circuit 304 receives the MET_{EVEN} signal from the logic OR gate 240. In this manner, if the MET_{ODD} signal corresponds to one of the odd-based comparators of the flash circuit 210 being metastable, the multiplexer circuit 304 outputs the even-based digital signal (DATA_{EVEN}). If the MET_{EVEN} signal corresponds to one of the even-based comparators of the flash circuit 210 being metastable, the multiplexer circuit 304 outputs the odd-based digital signal (DATA_{ODD}). If neither the MET_{ODD} or the MET_{EVEN} signals correspond to metastability, the multiplexer circuit 304 outputs the average of the odd-based digital signal (DATA_{ODD}) and the even-based digital signal (DATA_{EVEN}).

FIG. 3B illustrates an example table 310 illustrating the final digital output (e.g., ADC_OUT) of the multiplexer circuit 304 based on the MET_{EVEN} and MET_{ODD} signals, according to an embodiment of the present disclosure. In the table 310 of FIG. 3B, a ‘0’ for the MET signals corresponds to no metastability and a‘1’ for the MET signals corresponds to metastability. Other implementations are also possible.

Based on the table 310, if the MET_{ODD} or the MET_{EVEN} signals are both ‘0’ corresponding to no metastability, the multiplexer circuit 304 outputs the average of the odd-based digital signal (DATA_{ODD}) and the even-based digital signal (DATA_{EVEN}). If the MET_{EVEN} signal is ‘1’ corresponding to metastability, the multiplexer circuit 304 outputs the odd-based digital signal (DATA_{ODD}). If the MET_{ODD} signal is ‘1’ corresponding to metastability, the multiplexer circuit 304 outputs the even-based digital signal (DATA_{EVEN}). As described above, it is not possible for both one of the odd-based comparators and one of the even-based comparators to be metastable at the same time. Thus, it is not possible for the MET_{ODD} or the MET_{EVEN} signals to both be ‘1.’

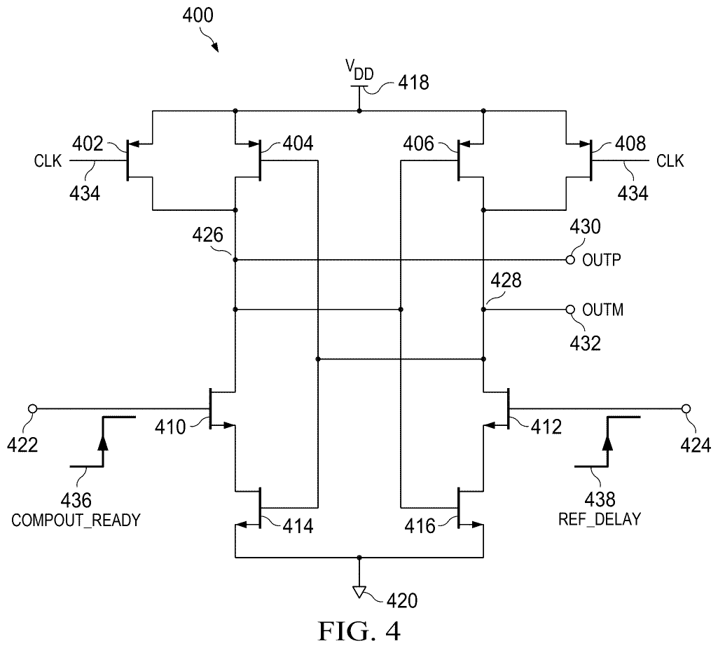

FIG. 4 is a schematic diagram of example metastability detection circuit 400 for one of the comparators of the flash circuit 210, according to an embodiment of the present disclosure. The metastability detection circuit 400 is duplicated for each of the comparators of the flash circuit 210. The metastability detection circuit 400 may be used to implement the metastability detection circuit 236 of FIG. 2A. The metastability detection circuit 400 includes example transistors 402, 404, 406, 408, 410, 412, 414, 416, example terminals 418, 420, 433, 424, 426, 428, 430, 432, 434, and example signals 436, 438. Other implementations may also be possible.

In an embodiment, the metastability detection circuit 400 is a delay domain comparator. In a delay domain comparator, the delay time corresponding to the inputs is compared rather than input voltages. The delay domain comparator can generate a ‘0’ or ‘1’ output depending on which of two input signals is received first. Metastability detection circuit 400 includes transistors 402, 404, 406, 408, 410, 412, 414, and 416. In one example, transistors 402, 404, 406, and 408 are p-type transistors. In one example, transistors 410, 412, 414, and 416 are n-type transistors. Transistors 402, 404, 406, 408, 410, 412, 414, and 416 are field effect transistors (FETs) in one example. Other types of transistors may be useful in other examples. Each of the transistors includes two current path terminals and a control terminal. For example, the two current path terminals of a FET are the source and the drain, and the control terminal is the gate.

The metastability detection circuit 400 also includes the first voltage terminal 418 and the second voltage terminal 420. The first voltage terminal 418 may receive a first voltage (such as VDD), and the second voltage terminal 420 may receive a second voltage (such as ground). The metastability detection circuit 400 also includes the first input terminal 422, the second input terminal 424, the first output node 426, and the second output node 428. The metastability detection circuit 400 includes the first output terminal 430 (OUTP) and the second output terminal 432 (OUTM). The COMPOUT_READY 436 (comparator output ready) is output from one or the comparators, or circuit(s) attached to the one comparator, in the flash circuit 210. The REF_DELAY 438 (reference delay) is a reference delay clock used to determine metastability.

In operation, the COMPOUT_READY signal 436 is the signal from one of the comparators in the flash circuit 210 that indicates the comparator has provided an output signal and is not metastable. The REF_DELAY 438 signal is a periodic signal that provides a pulse at a particular frequency, such as a pulse every 160 picoseconds (ps). The REF_DELAY 438 signal indicates how much time the comparators in flash circuit 210 are given to produce an output. If the COMPOUT_READY signal 436 arrives (e.g., transitions from a logic low to a logic high) at the metastability detection circuit 400 before the REF_DELAY signal 438, the transistor 410 turns on (e.g., conducts to operate as a closed circuit) before the transistor 412, and the first output node 426 is pulled down to the voltage value at the second voltage terminal 420 (e.g., ground). The voltage value at the first output terminal 430 (OUTP) is therefore low, and the metastability detection circuit 400 produces a ‘0’ output across OUTP and OUTM. The ‘0’ output indicates that the comparator in the flash circuit 210 coupled to the metastability detection circuit 400 is not metastable.

In another example, if the COMPOUT_READY signal 436 arrives (e.g., transitions from a logic low to a logic high) at the metastability detection circuit 400 after the REF_DELAY signal 438 (e.g., after 160 ps), the transistor 412 turns on before the transistor 410, and the second output node 428 is pulled down to the voltage value at the second voltage terminal 420 (e.g., ground). The voltage value at the second output terminal 432 (OUTM) is therefore low, and the metastability detection circuit 400 produces a ‘1’ output across OUTP and OUTM. The ‘1’ output indicates that the comparator in the flash circuit 210 coupled to the metastability detection circuit 400 has not produced an output after 160 ps and is metastable. If any metastability detection circuit 400 for a comparator of the flash circuit 210 produces a ‘1’ output, the corresponding comparator of the flash circuit 210 is considered metastable. If all the metastability comparators within the metastability detection circuit 236 produce a ‘0’ output, then each comparator in the flash circuit 210 has resolved within 160 ps.

FIG. 5 is a circuit implementation of an example ADC stage 500 of a pipelined ADC, according to an embodiment of the present disclosure. The ADC stage 500 may be used to implement the first stage 102 of the pipelined ADC 100 of FIG. 1. The ADC stage 500 includes the example buffers 202, 208, the example sampling circuit 203, the example switch 204, the example sampling capacitor 206, the example flash circuit 210, the example residue generation circuits 212, 224, the example switches 214, 218, 220, 230, 232, the example capacitors 216, 228, the example amplifiers 222, 234, the example metastability detection circuit 236, and the example logic gates 238, 240 of FIG. 2A. The ADC 500 further includes back end (BE) ADCs 501, 503, 505, example voltage to delay converters (V2Ds) 502, 504, 506, 508, 510, 512, 514, example switches 516, 518, 520, and example TDCs 522, 524, 526. The TDC 522 corresponds to the TDC 104a of FIG. 1 and the TDC 526 corresponds to the TDC 104b of FIG. 1. Although FIG. 2A illustrates a particular ADC sample stage 500, the first stage 102 can be implemented in a different manner. Other implementations are also possible.

Each ADC 501, 503, 505 converts the analog voltage to a digital voltage that corresponds to the least significant bits of the input voltage. For example, the ADC 501 converts the analog VRES_{ODD} residual voltage to digital values, the ADC 505 converts the analog VRES_{EVEN} residual voltage to digital values, and the ADC 503 converts a reference analog voltage (Vref) to a digital value. Because the TDCs 522, 524, 526 convert a time delay to digital values, each ADC 501, 503, 505 includes voltage to delay converters that convert an input voltage to a particular delay. For example, the ODD V2Ds 502, 506 convert the VRES_{ODD} to a time delay, the EVEN V2Ds 510, 514 convert the VRES_{EVEN} to a time delay, and the DAC V2Ds 504, 508, 512 convert a reference analog voltage to a time delay.

TDCs typically are calibrated to mitigate non-linearities and other errors inherent to TDCs. Thus, in some embodiments, the TDCs 522, 526 use a separate cycle to calibrate. Thus, the structure of FIG. 5 is structured to have the TDC 524 generate digital outputs based on the VRES_{ODD} voltage while the ODD TDC 522 is calibrating and the TDC 524 generates digital outputs based on the VRES_{EVEN} voltage while the EVEN TDC 526 is calibrating. For example, when neither the ODD TDC 522 nor the EVEN TDC 526 are being calibrated, the switches 516, 518, 520 are controlled so that the output of the V2D 502 is applied to the TDC 522 to generate ODD-based digital outputs. The output of V2D 514 is applied to the TDC 526 to generate EVEN-based digital outputs. The output of V2D 508 is applied to TDC 525 to generate digital outputs corresponding to Vref. When neither the ODD TDC 522 or the EVEN TDC 526 are being calibrated, the TDC 524 can be calibrated based on a difference between the digital outputs of TDC 524 and the known Vref voltage.

When the ODD TDC 522 is being calibrated, the switches 516, 218, 520 are controlled so that the V2D 504 is applied to the TDC 522, the V2D 506 is applied to the TDC 524, and the V2D 514 is applied to the TDC 526. In this manner, the TDC 522 can be calibrated by comparing the digital outputs to the reference voltage Vref and the TDC 524 can output the ODD-based digital results to the alignment and error correction circuitry 108. Thus, even during the cycle when the TDC 522 is being calibrated, the ODD-based digital outputs are still provided to the alignment and error correction circuitry 108. Finally, when the EVEN TDC 526 is being calibrated, the switches 516, 218, 520 are controlled so that the V2D 502 is applied to the TDC 522, the V2D 510 is applied to the TDC 524, and the V2D 512 is applied to the TDC 526. In this manner, the TDC 526 can be calibrated by comparing the digital outputs to the reference voltage Vref and the TDC 524 can output the EVEN-based digital results to the alignment and error correction circuitry 108. Thus, even during the cycle when the TDC 526 is being calibrated, the EVEN-based digital outputs are still provided to the alignment and error correction circuitry 108. The outputs of each TDC 522, 524, 526 is provided to the alignment and error correction circuitry 108, which determines how to process the outputs based on which TDC is being calibrated, if any.

Because the TDC 534 is shared by the TDCs 522, 526, the TDCs 522, 526 may not be calibrated at the same time. However, by sharing the TDC 534 (as opposed to having two TDCs—one for calibration of TDC 522 and another for calibration of TDC 526), space, power, and cost are conserved.

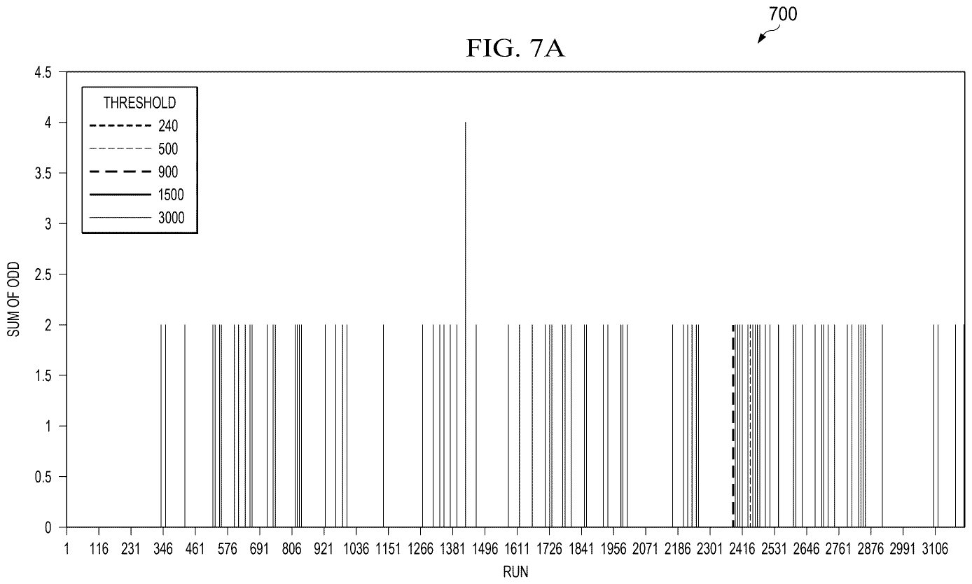

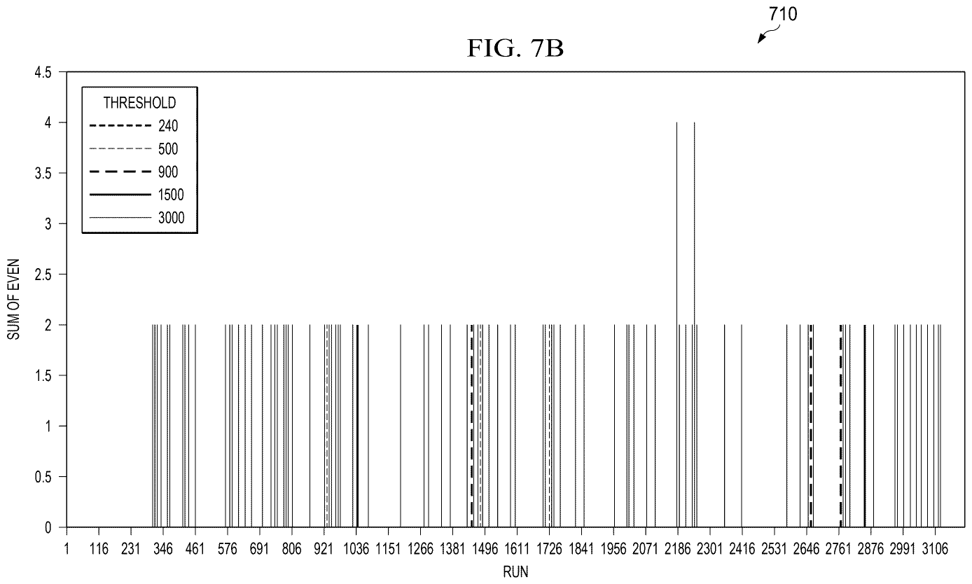

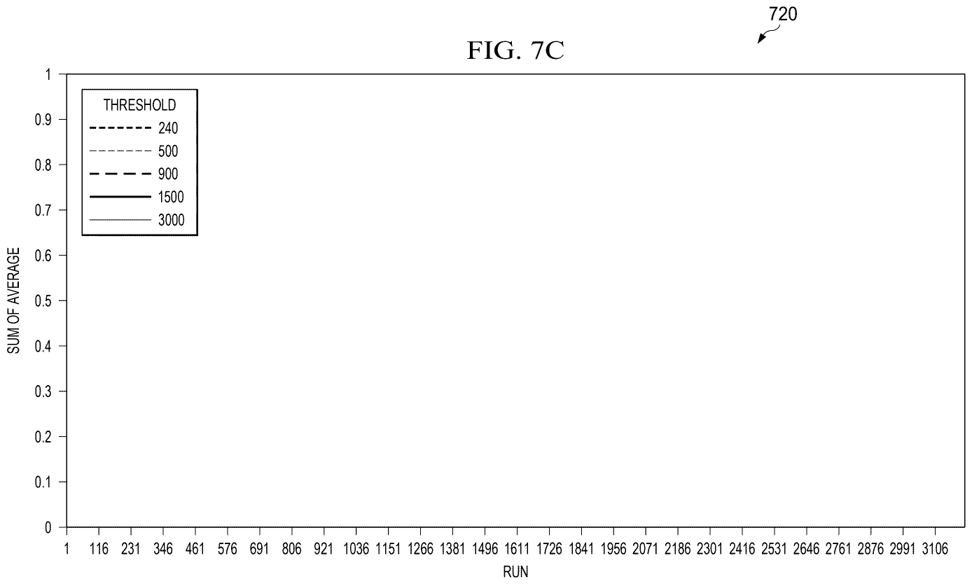

As described above, in some embodiments, the TDC architecture is inherently metastability free. Thus, because the ADC 100 is structured to remove the effect of metastability in the stage 102 of FIG. 1, the entire ADC 100 is free from metastability errors, as further illustrated below in conjunction with FIG. 7.

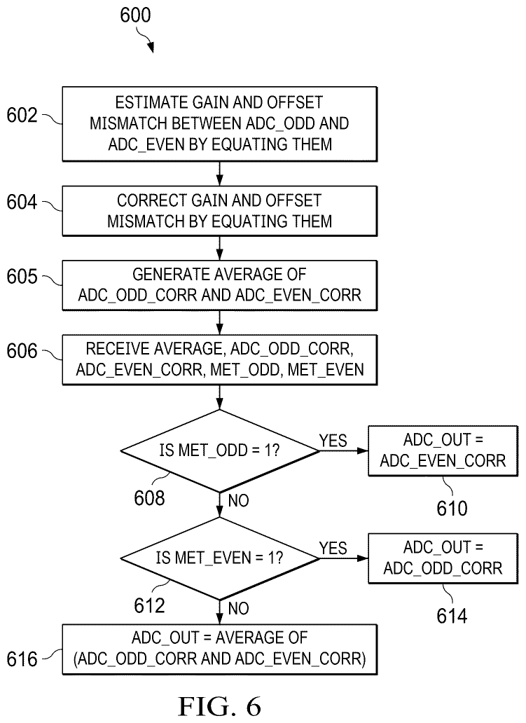

FIG. 6 is a flowchart of embodiment method 600, according to an embodiment of the present disclosure. Method 600 may be at least one of executed, instantiated, or performed by programmable circuitry to implement the alignment and error correction circuit 108 and/or the output stage 300 of FIG. 1 to generate a final digital output for the ADC 100 of FIG. 1. The steps/blocks of FIG. 6 are described with respect to the alignment and error correction circuit 108 and/or the output stage 300 of FIG. 1.

Method 600 begins at block 602, in which the alignment and error correction circuit 108 estimates the gain and offset mismatch between the even-based digital output and the odd-based digital output. At block 604, the alignment and error correction circuit 108 corrects the gain and offset mismatch by equating the gain and offset between the even-based and odd-based digital signals, as described above. At block 605, the average circuit 302 of the output stage 110 generates an average of the corrected odd-based digital output (ADC_ODD_CORR) and the corrected even-based digital output (ADC_EVEN_CORR). At block 606, the multiplexer circuit 304 of the output stage 110 receives the average of the corrected odd-based digital output and the corrected even-based digital output from the averager circuit, the corrected odd-based digital output (ADC_ODD_CORR) from the alignment and error correction circuit 108, the even-based digital output (ADC_EVEN_CORR) from the alignment and error correction circuit 108, the odd-based metastability signal (MET_ODD) from the logic OR gate 238 of FIG. 2A, and the even-based metastability signal (MET_EVEN) from the logic OR gate 240 of FIG. 2A.

At block 608, the multiplexer circuit 304 determines if the odd-based digital output corresponds to metastability (e.g., MET_ODD=1). If the multiplexer circuit 304 determines that the odd-based digital output corresponds to metastability (block 608: YES), the multiplexer 304 outputs the corrected even-based digital output (ADC_EVEN_CORR) as the final output of the ADC 100 (block 610). If the multiplexer circuit 304 determines that the odd-based digital output corresponds to metastability (block 608: NO), the multiplexer circuit 304 determines if the even-based digital output corresponds to metastability (e.g., MET_EVEN=1) (block 612). If the multiplexer circuit 304 determines that the even-based digital output corresponds to metastability (block 612: YES), the multiplexer 304 outputs the corrected odd-based digital output (ADC_ODD_CORR) as the final output of the ADC 100 (block 614). If the multiplexer circuit 304 determines that the even-based digital output corresponds to metastability (block 612: NO), the multiplexer circuit 304 outputs the average of the corrected odd-based digital output (ADC_ODD_CORR) and the corrected even-based digital output (ADC_EVEN_CORR) as the final output of the ADC 100 (block 616).

FIGS. 7A-7C illustrate a comparison of metastability events across multiple ADC samples, according to an embodiment of the present disclosure. FIG. 7A includes a timing diagram 700 with metastability events across multiple ADC samples for different code error thresholds for the odd-based digital output. FIG. 7B includes a timing diagram 710 with metastability events across multiple ADC samples for different code error thresholds for the even-based digital output. FIG. 7C includes a timing diagram 720 with metastability events across multiple ADC samples for different code error thresholds for the final digital output of the ADC 100 of FIG. 1. Other implementations are also possible. As shown in the timing diagrams 700, 710, there are a number of metastability events for the odd-based digital outputs and the even-based digital outputs across the multiple samples. However, as shown in the timing diagram 720, there are no metastability events for the final digital output of the ADC 100 of FIG. 1, because when an odd-based metastability event occurs, the ADC 100 outputs the even-based digital output and when an even-based metastability event occurs, the ADC 100 outputs the odd-based digital output, thereby avoiding all metastability events at the final output of the ADC 100.

While an example manner of implementing the ADC 100 of FIG. 1 is illustrated in FIG. 1, an example manner of implementing the ADC stage 102 is illustrated in FIG. 2A, an example manner of implementing the flash circuit 210 of FIG. 2A is illustrated in FIG. 2B, an example manner of implementing the output stage 110 of FIG. 1 is illustrated in FIG. 3, and an example manner of implementing the metastability detection circuit 236 is illustrated in FIG. 4,, one or more of the elements, processes, and/or devices illustrated in FIGS. 1-4 may be combined, divided, re-arranged, omitted, eliminated, and/or implemented in any other way. Further, the stage 102, the TDCs 104a, 104b, the alignment and error correction circuit 108, the output stage 110, the flash circuit 210, and/or the metastability detection circuit 236 of FIGS. 1-6 may be implemented by hardware alone or by hardware in combination with software and/or firmware. Thus, for example, any of the stage 102, the TDCs 104a, 104b, the alignment and error correction circuit 108, the output stage 110, the flash circuit 210, and/or the metastability detection circuit 236 of FIGS. 1-6 could be implemented by programmable circuitry, processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), vision processing units (VPUs), and/or field programmable logic device(s) (FPLD(s)) such as FPGAs in combination with machine readable instructions (e.g., firmware or software). Further still, the stage 102, the TDCs 104a, 102b, the alignment and error correction circuit 108, the output stage 110, the flash circuit 210, and/or the metastability detection circuit 236 of FIGS. 1-6 may include one or more elements, processes, and/or devices in addition to, or instead of, those illustrated in FIGS. 1-6, and/or may include more than one of any or all of the illustrated elements, processes and devices.

Flowchart(s) representative of example machine readable instructions, which may be executed by programmable circuitry to implement and/or instantiate the alignment and error correction circuit 108 and/or the output stage 300 of FIGS. 1 and/or 3 and/or representative of example operations which may be performed by programmable circuitry to implement and/or instantiate the alignment and error correction circuit 108 and/or the output stage 300, are shown in FIG. 6. The machine-readable instructions may be one or more executable programs or portion(s) of one or more executable programs for execution by programmable circuitry. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. Similarly, the non-transitory computer readable storage medium may include one or more mediums.

Although the example program is described with reference to the flowchart(s) illustrated in FIG. 6, many other methods of implementing the alignment and error correction circuit 108 and/or the output stage 300 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)).

As used herein, programmable circuitry includes any type(s) of circuitry that may be programmed to perform a desired function such as, for example, a CPU, a GPU, a VPU, and/or an FPGA. The programmable circuitry may include one or more CPUs, one or more GPUs, one or more VPUs, and/or one or more FPGAs located in the same package (e.g., the same integrated circuit (IC) package or in two or more separate housings), one or more CPUs, GPUs, VPUs, and/or one or more FPGAs in a single machine, multiple CPUs, GPUs, VPUs, and/or FPGAs distributed across multiple servers of a server rack, and/or multiple CPUs, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

As used herein, “programmable circuitry” may include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

Example embodiments of the present disclosure are summarized here. Other embodiments can also be understood from the entirety of the specification and the claims filed herein.

Example 1. An apparatus including: a first set of comparators configured to compare a sampled analog voltage to first thresholds, the first thresholds being at first indices of a set of thresholds; a second set of comparators configured to compare the sampled analog voltage to second thresholds, the second thresholds being at second indices of the set of thresholds, the second indices different than the first indices; a first set of capacitors configured to decrease the sampled analog voltage by a first reference voltage based on the outputs of the first set of comparators, the decreased sampled analog voltage corresponding to a first residual voltage; a second set of capacitors configured to decrease the sampled analog voltage by a second reference voltage based on the outputs of the second set of comparators, the decreased sampled analog voltage corresponding to a second residual voltage; a metastability detection circuit configured to determine whether one of the first set of comparators or the second set of comparators is metastable; and a multiplexer circuit configured to output a digital signal corresponding to the first residual voltage based on a comparator of the second set of comparators being metastable.

Example 2. The apparatus of example 1, where the digital signal is a first digital signal corresponding to the first residual voltage, the apparatus further including an averager circuit configured to output an average of the first digital signal with a second digital signal corresponding to the second residual voltage, the first digital signal and the second digital signal corresponding to the sampled analog voltage.

Example 3. The apparatus of one of examples 1 or 2, where the multiplexer circuit is configured to output the average of the first digital signal and the second digital signal based on the first and second sets of comparators not being metastable.

Example 4. The apparatus of one of examples 1 to 3, where: a comparator of the first set of comparators or the second set of comparators is configured to output a ready signal after an output of the comparator is valid; and the metastability detection circuit configured to determine that the comparator is metastable based on a comparison of the output of the comparator to a clock signal.

Example 5. The apparatus of one of examples 1 to 4, where: a comparator of the first set of comparators or the second set of comparators is configured to output a ready signal after an output of the comparator is valid; and the metastability detection circuit is configured to determine that the comparator is metastable based on a predetermined duration of time for the comparator to output the ready signal.

Example 6. The apparatus of one of examples 1 to 5, where the first and second set of comparators are configured to operate as a flash analog-to-digital converter.

Example 7. The apparatus of one of examples 1 to 6, further including a sampling capacitor configured to store the sampled analog voltage.

Example 8. The apparatus of one of examples 1 to 7, further including an analog-to-digital converter (ADC) including: a first stage that includes the first set of comparators and the second set of comparators; a first amplifier configured to output an amplified first residual voltage to a subsequent stage of the ADC based on the first residual voltage; and a second amplifier configured to output an amplified second residual voltage to the subsequent stage based on the second residual voltage.

Example 9. The apparatus of one of examples 1 to 8, further including: a first switch coupled to a first capacitor of the first set of capacitors and a first reference voltage source; a second switch coupled to the first capacitor of the first set of capacitors and a ground terminal; a third switch coupled to a first capacitor of the second set of capacitors and a second reference voltage source different than the first reference voltage source; and a fourth switch coupled to the first capacitor of the second set of capacitors and the ground terminal.

Example 10. The apparatus of one of examples 1 to 9, where a first output of a first comparator of the first set of comparators is configured to control the first and second switch, and a second output of a first comparator of the second set of comparators is configured to control the third and fourth switch.

Example 11. The apparatus of one of examples 1 to 10, where the first reference voltage source and the second reference voltage source are each configured to output the same reference voltage.

Example 12. The apparatus of one of examples 1 to 11, where the first indices correspond to even increments and the second indices correspond to odd increments.

Example 13. The apparatus of one of examples 1 to 12, where differences between subsequent thresholds in the first thresholds are non-uniform.

Example 14. An apparatus including: a sample and hold circuit having an input and an output; a flash circuit including an input, first outputs and second outputs, the input of the flash circuit coupled to the output of the sample and hold circuit, the flash circuit including: a set of reference terminals, each reference terminal of the set of reference terminals corresponding to a different reference voltage, the set of reference terminals including a first subset of the set of reference terminals and a second subset of the set of reference terminals, the first subset of the set of reference terminals corresponding to a first parity of a sequence and the second subset of the set of reference terminals corresponding to a second parity of the sequence; a first set of comparators, each having a first input, a second input, and an output, the first inputs of the first set of comparators coupled to the output of the sample and hold circuit, the second inputs of the first set of comparators coupled to corresponding ones of the first subset of the set of reference terminals, the outputs of the first set of comparators coupled to corresponding ones of the first outputs of the flash circuit; and a second set of comparators, each having a first input, a second input, and an output, the first inputs of the second set of comparators coupled to the output of the sample and hold circuit, the second inputs of the second set of comparators coupled to corresponding ones of the second subset of the set of reference terminals, the outputs of the second set of comparators coupled to corresponding ones of the second outputs of the flash circuit; a buffer having an input and an output, the input of the buffer coupled to the output of the sample and hold circuit; a first set of capacitors, each having a first terminal and a second terminal, the first terminals of the first set of capacitors coupled to the output of the buffer, the second terminals of the first set of capacitors coupled to a first reference voltage supply through corresponding first switches and a ground terminal through corresponding second switches, control terminals of the of the first switches and second switches coupled to corresponding outputs of the first set of comparators; a second set of capacitors, each having a first terminal and a second terminal, the first terminals of the second set of capacitors coupled to the output of the buffer, the second terminals of the second set of capacitors coupled to a second reference voltage supply through corresponding third switches and the ground terminal through corresponding fourth switches, control terminals of the of the third and fourth switches coupled to corresponding outputs of the second set of comparators; a first amplifier having an input and an output, the input of the first amplifier coupled to the first terminals of the first set of capacitors, the output of the first amplifier coupled to a subsequent stage; and a second amplifier having an input and an output, the input of the second amplifier coupled to the first terminals of the second set of capacitors, the output of the second amplifier coupled to the subsequent stage.

Example 15. The apparatus of example 14, where the subsequent stage includes a time to digital converter (TDC).

Example 16. The apparatus of one of examples 14 or 15, where the flash circuit further has third outputs and fourth outputs, the third outputs corresponding to the outputs of the first set of comparators, the fourth outputs corresponding to the second set of comparators, further including: a metastability detection circuit having inputs, first outputs, and second outputs, the inputs of the metastability detection circuit coupled to corresponding ones of the third outputs and the fourth outputs; a first logic OR gate having inputs and an output, the inputs of the first logic OR gate coupled to corresponding ones of the first outputs of the metastability detection circuit; and a second logic OR gate having inputs and an output, the inputs of the second logic OR gate coupled to corresponding ones of the second outputs of the metastability detection circuit.

Example 17. The apparatus of one of examples 14 to 16, further including: alignment and error correction circuit including first inputs, second inputs, a first output, and a second output, the first inputs of the alignment and error correction circuit coupled to corresponding ones of the first outputs of the first set of comparators and corresponding ones of the first outputs of the second set of comparators, the second inputs of the alignment and error correction circuit coupled to corresponding outputs of the subsequent stage; an averager circuit including a first input, a second input, and an output, the first input of the averager circuit coupled to the first output of the alignment and error correction circuit, the second input of the averager circuit coupled to the second output of the alignment and error correction circuit; and a multiplexer circuit including a first input, a second input, a third input, a first select input, a second select input, and an output, the first input of the multiplexer circuit coupled to the first output of the alignment and error correction circuit, the second input of the multiplexer circuit coupled to the second output of the alignment and error correction circuit, the third input of the multiplexer circuit coupled to the output of the averager circuit, the first select input of the multiplexer circuit coupled to the output of the first logic OR gate, the second select input of the multiplexer circuit coupled to the output of the second logic OR gate.

Example 18. The apparatus of one of examples 14 to 17, where the first reference voltage supply is different than the second reference voltage supply and a voltage output by the first reference voltage supply is the same as a voltage output by the second reference voltage supply.

Example 19. The apparatus of one of examples 14 to 18, where the first reference voltage supply is different from the second voltage supply.

Example 20. A method including: sampling an input analog voltage; generating a first residual voltage based on the sampled input analog voltage and a first set of comparisons of the sampled input analog voltage to a first set of thresholds; generating a second residual voltage based on the sampled input analog voltage and a second set of comparisons of the sampled input analog voltage to a second set of thresholds; generating a first digital output corresponding to the input analog voltage based on the first set of comparisons and a third set of comparisons based on the first residual voltage; generating a second digital output corresponding to the input analog voltage based on the second set of comparisons and a fourth set of comparisons based on the second residual voltage; and generating a final digital output by averaging the first digital output and the second digital output.

Example 21. The method of example 20, where a set of thresholds includes the first set of thresholds and the second set of thresholds, the first set of thresholds corresponding to even increments of the set of thresholds and the second set of thresholds corresponding to odd increments of the set of thresholds.

Example 22. The method of one of examples 20 or 21, where the first set of comparisons is performed using the first set of comparators and the second set of comparisons is performed using a second set of comparators, further including determining whether one of the first and second set of comparators is metastable, the generating of a final digital output based on none of the first and second set of comparators being metastable.

While this disclosure has been described with reference to illustrative embodiments, this description is not limiting. Various modifications and combinations of the illustrative embodiments, as well as other embodiments, will be apparent to persons skilled in the art upon reference to the description.

What is claimed is:

1. An apparatus comprising:
a first set of comparators configured to compare a sampled analog voltage to first thresholds, the first thresholds being at first indices of a set of thresholds;
a second set of comparators configured to compare the sampled analog voltage to second thresholds, the second thresholds being at second indices of the set of thresholds, the second indices different than the first indices;
a first set of capacitors configured to decrease the sampled analog voltage by a first reference voltage based on the outputs of the first set of comparators, the decreased sampled analog voltage corresponding to a first residual voltage;
a second set of capacitors configured to decrease the sampled analog voltage by a second reference voltage based on the outputs of the second set of comparators, the decreased sampled analog voltage corresponding to a second residual voltage;
a metastability detection circuit configured to determine whether one of the first set of comparators or the second set of comparators is metastable; and
a multiplexer circuit configured to output a digital signal corresponding to the first residual voltage based on a comparator of the second set of comparators being metastable.

2. The apparatus of claim 1, wherein the digital signal is a first digital signal corresponding to the first residual voltage, the apparatus further including an averager circuit configured to output an average of the first digital signal with a second digital signal corresponding to the second residual voltage, the first digital signal and the second digital signal corresponding to the sampled analog voltage.

3. The apparatus of claim 2, wherein the multiplexer circuit is configured to output the average of the first digital signal and the second digital signal based on the first and second sets of comparators not being metastable.

4. The apparatus of claim 1, wherein:
a comparator of the first set of comparators or the second set of comparators is configured to output a ready signal after an output of the comparator is valid; and
the metastability detection circuit configured to determine that the comparator is metastable based on a comparison of the output of the comparator to a clock signal.

5. The apparatus of claim 1, wherein:
a comparator of the first set of comparators or the second set of comparators is configured to output a ready signal after an output of the comparator is valid; and
the metastability detection circuit is configured to determine that the comparator is metastable based on a predetermined duration of time for the comparator to output the ready signal.

6. The apparatus of claim 1, wherein the first and second set of comparators are configured to operate as a flash analog-to-digital converter.

7. The apparatus of claim 1, further including a sampling capacitor configured to store the sampled analog voltage.

8. The apparatus of claim 1, further including an analog-to-digital converter (ADC) comprising:
a first stage that comprises the first set of comparators and the second set of comparators;
a first amplifier configured to output an amplified first residual voltage to a subsequent stage of the ADC based on the first residual voltage; and
a second amplifier configured to output an amplified second residual voltage to the subsequent stage based on the second residual voltage.

9. The apparatus of claim 1, further including:
a first switch coupled to a first capacitor of the first set of capacitors and a first reference voltage source;
a second switch coupled to the first capacitor of the first set of capacitors and a ground terminal;
a third switch coupled to a first capacitor of the second set of capacitors and a second reference voltage source different than the first reference voltage source; and
a fourth switch coupled to the first capacitor of the second set of capacitors and the ground terminal.

10. The apparatus of claim 9, wherein a first output of a first comparator of the first set of comparators is configured to control the first and second switch, and a second output of a first comparator of the second set of comparators is configured to control the third and fourth switch.

11. The apparatus of claim 9, wherein the first reference voltage source and the second reference voltage source are each configured to output the same reference voltage.

12. The apparatus of claim 1, wherein the first indices correspond to even increments and the second indices correspond to odd increments.

13. The apparatus of claim 1, wherein differences between subsequent thresholds in the first thresholds are non-uniform.

14. An apparatus comprising:
a sample and hold circuit having an input and an output;
a flash circuit including an input, first outputs and second outputs, the input of the flash circuit coupled to the output of the sample and hold circuit, the flash circuit including:
a set of reference terminals, each reference terminal of the set of reference terminals corresponding to a different reference voltage, the set of reference terminals including a first subset of the set of reference terminals and a second subset of the set of reference terminals, the first subset of the set of reference terminals corresponding to a first parity of a sequence and the second subset of the set of reference terminals corresponding to a second parity of the sequence;
a first set of comparators, each having a first input, a second input, and an output, the first inputs of the first set of comparators coupled to the output of the sample and hold circuit, the second inputs of the first set of comparators coupled to corresponding ones of the first subset of the set of reference terminals, the outputs of the first set of comparators coupled to corresponding ones of the first outputs of the flash circuit; and
a second set of comparators, each having a first input, a second input, and an output, the first inputs of the second set of comparators coupled to the output of the sample and hold circuit, the second inputs of the second set of comparators coupled to corresponding ones of the second subset of the set of reference terminals, the outputs of the second set of comparators coupled to corresponding ones of the second outputs of the flash circuit;
a buffer having an input and an output, the input of the buffer coupled to the output of the sample and hold circuit;
a first set of capacitors, each having a first terminal and a second terminal, the first terminals of the first set of capacitors coupled to the output of the buffer, the second terminals of the first set of capacitors coupled to a first reference voltage supply through corresponding first switches and a ground terminal through corresponding second switches, control terminals of the of the first switches and second switches coupled to corresponding outputs of the first set of comparators;
a second set of capacitors, each having a first terminal and a second terminal, the first terminals of the second set of capacitors coupled to the output of the buffer, the second terminals of the second set of capacitors coupled to a second reference voltage supply through corresponding third switches and the ground terminal through corresponding fourth switches, control terminals of the of the third and fourth switches coupled to corresponding outputs of the second set of comparators;
a first amplifier having an input and an output, the input of the first amplifier coupled to the first terminals of the first set of capacitors, the output of the first amplifier coupled to a subsequent stage; and
a second amplifier having an input and an output, the input of the second amplifier coupled to the first terminals of the second set of capacitors, the output of the second amplifier coupled to the subsequent stage.

15. The apparatus of claim 14, wherein the subsequent stage comprises a time to digital converter (TDC).

16. The apparatus of claim 14, wherein the flash circuit further has third outputs and fourth outputs, the third outputs corresponding to the outputs of the first set of comparators, the fourth outputs corresponding to the second set of comparators, further including:
a metastability detection circuit having inputs, first outputs, and second outputs, the inputs of the metastability detection circuit coupled to corresponding ones of the third outputs and the fourth outputs;
a first logic OR gate having inputs and an output, the inputs of the first logic OR gate coupled to corresponding ones of the first outputs of the metastability detection circuit; and
a second logic OR gate having inputs and an output, the inputs of the second logic OR gate coupled to corresponding ones of the second outputs of the metastability detection circuit.

17. The apparatus of claim 16, further including:
alignment and error correction circuit including first inputs, second inputs, a first output, and a second output, the first inputs of the alignment and error correction circuit coupled to corresponding ones of the first outputs of the first set of comparators and corresponding ones of the first outputs of the second set of comparators, the second inputs of the alignment and error correction circuit coupled to corresponding outputs of the subsequent stage;
an averager circuit including a first input, a second input, and an output, the first input of the averager circuit coupled to the first output of the alignment and error correction circuit, the second input of the averager circuit coupled to the second output of the alignment and error correction circuit; and
a multiplexer circuit including a first input, a second input, a third input, a first select input, a second select input, and an output, the first input of the multiplexer circuit coupled to the first output of the alignment and error correction circuit, the second input of the multiplexer circuit coupled to the second output of the alignment and error correction circuit, the third input of the multiplexer circuit coupled to the output of the averager circuit, the first select input of the multiplexer circuit coupled to the output of the first logic OR gate, the second select input of the multiplexer circuit coupled to the output of the second logic OR gate.

18. The apparatus of claim 14, wherein the first reference voltage supply is different than the second reference voltage supply and a voltage output by the first reference voltage supply is the same as a voltage output by the second reference voltage supply.

19. The apparatus of claim 14, wherein the first reference voltage supply is different from the second voltage supply.

20. A method comprising:
sampling an input analog voltage;
generating a first residual voltage based on the sampled input analog voltage and a first set of comparisons of the sampled input analog voltage to a first set of thresholds;
generating a second residual voltage based on the sampled input analog voltage and a second set of comparisons of the sampled input analog voltage to a second set of thresholds;
generating a first digital output corresponding to the input analog voltage based on the first set of comparisons and a third set of comparisons based on the first residual voltage;
generating a second digital output corresponding to the input analog voltage based on the second set of comparisons and a fourth set of comparisons based on the second residual voltage; and
generating a final digital output by averaging the first digital output and the second digital output.

21. The method of claim 20, wherein a set of thresholds includes the first set of thresholds and the second set of thresholds, the first set of thresholds corresponding to even increments of the set of thresholds and the second set of thresholds corresponding to odd increments of the set of thresholds.

22. The method of claim 20, wherein the first set of comparisons is performed using the first set of comparators and the second set of comparisons is performed using a second set of comparators, further including determining whether one of the first and second set of comparators is metastable, the generating of a final digital output based on none of the first and second set of comparators being metastable.
